(19) United States
(12) Patent Application Publication
(10) Pub. No.: US 2025/0038063 A1
(43) Pub. Date: Jan. 30, 2025

(54) CHIP PACKAGING STRUCTURE, SEMICONDUCTOR STRUCTURE, AND FABRICATING METHOD THEREOF

(71) Applicant: YANGTZE MEMORY TECHNOLOGIES CO., LTD., Wuhan (CN)

(72) Inventors: Xin Feng, Wuhan (CN); Shanshan Zhao, Wuhan (CN); Peng Chen, Wuhan (CN); Ping Mo, Wuhan (CN)

(21) Appl. No.: 18/234,337

(22) Filed: Aug. 15, 2023

Related U.S. Application Data
(63) Continuation of application No. PCT/CN2023/109252, filed on Jul. 26, 2023.

(51) Int. Cl. H01L 23/367; H01L 23/00; H01L 23/373; H01L 23/498; H01L 25/00; H01L 25/065

(52) U.S. Cl. CPC H01L 23/3675; H01L 23/3738; H01L 23/49816; H01L 24/48; H01L 25/0655; H01L 25/50; H01L 24/32; H01L 2224/32225; H01L 2224/48105; H01L 2224/48227; H01L 2225/065; H01L 2924/16251

(57) ABSTRACT

Implementations of chip packaging structures, semiconductor structures and fabricating methods thereof are disclosed. A chip packaging structure comprises a substrate comprising: a signal transmitting wiring structure embedded in the substrate, and a thermal transmitting wiring structure embedded in the substrate. The chip packaging structure further comprises a first chip on the substrate and electrically connected with the signal transmitting wiring structure. The chip packaging structure further comprises at least one thermal conductive structure on the substrate, in thermal contact with the thermal transmitting wiring structure, and laterally surrounding the first chip.

### CROSS-REFERENCE TO RELATED APPLICATIONS

This application is a continuation of International Application No. PCT/CN2023/109252, filed on Jul. 26, 2023, entitled “CHIP PACKAGING STRUCTURE, SEMICONDUCTOR STRUCTURE, AND FABRICATING METHOD THEREOF,” which is incorporated herein by reference in its entirety.

### TECHNICAL FIELD

The present disclosure generally relates to the field of semiconductor technology, and more particularly, to chip packaging structures, related semiconductor structures, and fabricating methods thereof.

### BACKGROUND

As the continues increasing of the power consumption of semiconductor chips, the requirements for heat dissipation of packages become higher. However, the package material has a poor thermal conductivity on one hand, and the existing heat dissipation methods are mostly processed at the system level on the other hand. There is a demand for special heat conduction channels inside the chip packages.

### BRIEF SUMMARY

Implementations of chip packaging structures, semiconductor structures and fabricating methods thereof are described in the present disclosure.

One aspect of the present disclosure provides a chip packaging structure, comprising: a substrate, comprising: a signal transmitting wiring structure embedded in the substrate, and a thermal transmitting wiring structure embedded in the substrate; a first chip on the substrate and electrically connected with the signal transmitting wiring structure; and at least one thermal conductive structure on the substrate, in thermal contact with the thermal transmitting wiring structure, and laterally surrounding the first chip.

In some implementations, the chip packaging structure further comprises: a mold compound layer on the substrate and covering the first chip, wherein the at least one thermal conductive structure is embedded in the mold compound layer; and a thermal conductive cover on the mold compound layer and in thermal contact with the at least one thermal conductive structure.

In some implementations, the chip packaging structure further comprises: a ball grid array on a side of substrate opposite to the first chip and the at least one thermal conductive structure, the ball grid array comprising: a plurality of signal solder balls in contact with the signal transmitting wiring structure, and at least one thermal solder ball in contact with the thermal transmitting wiring structure.

In some implementations, the at least one thermal conductive structure comprises: a plurality of thermal conductive blocks each vertically penetrating through the mold compound layer and comprising a top surface in contact with the thermal conductive cover and a bottom surface in contact with a thermal pad connected with the thermal transmitting wiring structure.

In some implementations, a ratio between a first lateral area of each thermal conductive block and a second lateral area of the first chip is in a range between about 1/20 and about 1/10.

In some implementations, the chip packaging structure further comprises: a second chip on the substrate and outside the at least one thermal conductive structure.

In some implementations, the chip packaging structure further comprises: a first operating power of the first chip is greater than a second operating power of the second chip.

In some implementations, the first chip comprises at least one of a micro processing chip, a logic control chip, a power management chip, a driver chip, and an analog chip; and the second chip comprises at least one of a memory chip and a sensing chip.

In some implementations, the chip packaging structure further comprises: a third chip on the substrate and beside the first chip, and being laterally surrounded by the at least one thermal conductive structure.

In some implementations, a portion of the at least one thermal conductive structure is located between the third chip and the first chip.

In some implementations, a material of the at least one thermal conductive structure has a thermal conductive coefficient greater than 1.

In some implementations, the material is one of a metal, a ceramic material, or a silicon material.

In some implementations, the chip packaging structure further comprises: a ratio between a first wiring width of the thermal transmitting wiring structure and a second wiring width of the signal transmitting wiring structure is in a range between about 1.5 to about 2.

Another aspect of the present disclosure provides a method of forming a chip packaging structure, comprising: providing a substrate, comprising: a signal transmitting wiring structure embedded in the substrate, and a thermal transmitting wiring structure embedded in the substrate; forming at least one thermal conductive structure on a first side of the substrate and in thermal contact with the thermal transmitting wiring structure; forming a first chip on the first side of the substrate and laterally surrounded by the first chip; and electrically connecting the first chip with the signal transmitting wiring structure.

In some implementations, the method further comprises: forming a mold compound layer on the first side of the substrate to cover the first chip and the at least one thermal conductive structure; and forming a thermal conductive cover on the mold compound layer on the mold compound layer and in thermal contact with the at least one thermal conductive structure.

In some implementations, the method further comprises: forming a ball grid array on a second side of substrate opposite to the first side, comprising: forming a plurality of signal solder balls in contact with the signal transmitting wiring structure, and forming at least one thermal solder ball in contact with the thermal transmitting wiring structure.

In some implementations, forming the at least one thermal conductive structure comprises: forming a plurality of thermal conductive blocks each on a thermal pad on the first side of the substrate and connected with the thermal transmitting wiring structure.

In some implementations, the at least one thermal conductive structure and the first chip are formed on the substrate by using a surface mount technology (SMT) process.

In some implementations, the method further comprises: forming a second chip on the first side of the substrate and outside the at least one thermal conductive structure, wherein a first operating power of the first chip is greater than a second operating power of the second chip.

Another aspect of the present disclosure provides a semiconductor structure, comprising: a printed circuit board; a chip packaging structure, comprising: a substrate, comprising: a signal transmitting wiring structure embedded in the substrate, and a thermal transmitting wiring structure embedded in the substrate; a first chip on the substrate and electrically connected with the signal transmitting wiring structure; and at least one thermal conductive structure on the substrate, in thermal contact with the thermal transmitting wiring structure, and laterally surrounding the first chip; and a ball grid array connected between the printed circuit board and the chip packaging structure, comprising: a plurality of signal solder balls in contact with the signal transmitting wiring structure, and at least one thermal solder ball in contact with the thermal transmitting wiring structure.

Other aspects of the present disclosure can be understood by those skilled in the art in light of the description, the claims, and the drawings of the present disclosure.

### BRIEF DESCRIPTION OF THE DRAWINGS

The accompanying drawings, which are incorporated herein and form a part of the specification, illustrate implementations of the present disclosure and, together with the description, further serve to explain the principles of the present disclosure and to enable a person skilled in the pertinent art to make and use the present disclosure.

FIG. 1 illustrates a schematic diagram in a perspective side view of an exemplary semiconductor structure, in accordance with some implementations of the present disclosure.

FIG. 2A illustrates a schematic diagram in a planar view of an exemplary semiconductor structure, in accordance with some implementations of the present disclosure.

FIG. 2B illustrates a schematic diagram in a planar view of another exemplary semiconductor structure, in accordance with some other implementations of the present disclosure.

FIG. 2C illustrates a schematic diagram in a planar view of another exemplary semiconductor structure, in accordance with some other implementations of the present disclosure.

FIG. 2D illustrates a schematic diagram in a planar view of another exemplary semiconductor structure, in accordance with some other implementations of the present disclosure.

FIG. 3 illustrates a flow diagram of an exemplary method for forming a semiconductor structure, in accordance with some implementations of the present disclosure.

FIGS. 4-9 illustrate schematic diagrams in a perspective side view of an exemplary semiconductor structure at certain fabricating steps of the method shown in FIG. 3, in accordance with some implementations of the present disclosure.

The features and advantages of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

Implementations of the present disclosure will be described with reference to the accompanying drawings.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one implementation,” “an implementation,” “an example implementation,” “some implementations,” etc., indicate that the implementation described can include a particular feature, structure, or characteristic, but every implementation can not necessarily include the particular feature, structure, or characteristic. Moreover, such phrases do not necessarily refer to the same implementation. Further, when a particular feature, structure or characteristic is described in connection with an implementation, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The front surface of the substrate is typically where a semiconductor device is formed, and therefore the semiconductor device is formed at a top side of the substrate unless stated otherwise. The bottom surface is opposite to the front surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer has a top side and a bottom side where the bottom side of the layer is adjacent to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. The range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

The present disclosure provides chip packaging structures with a high thermal conductivity. The fabricating process can be modularized. In a disclosed chip packaging space, a certain number of thermal conductive structures of same or different sizes can be packaged around the chip stack and connected between a metal layer on the front of the package and the solder balls on the back to realize a strong heat dissipation effect. Through the surface mount technology (SMT) packaging process, the connection between the high thermal conductivity material and the copper layer of the substrate and the connection of the surface metal coating can be realized. As such, high thermal conductivity within the packaging structure can be obtained, thereby significantly improving the product heat dissipation and improving the product performance.

The disclosed fabricating process for forming the disclosed chip packaging structures can be modularized, thus it is simple. Conventional equipment can be used for the disclosed fabricating process without much cost investment. The modular packaging solution can be adopted to reduce the difficulty of packaging and processing, which is conducive to mass production. The disclosed design can achieve better internal heat conduction effect of the chip packaging structure without changing the external dimensions of the existing package and the existing packaging materials. The thermal conductive structures can select a material with a high thermal conductivity and a high mechanical strength, so that the whole chip packaging structure can have a better heat dissipation effect and a better mechanical property. Further, the disclosed fabricating process can allow flexible design of different sizes and/or different quantities of thermal conductive structures according to space requirements. Therefore, the heat dissipation conditions of high-power chips within the disclosed chip packaging structures can be significantly improved, and the operating temperatures of the disclosed chip packaging structures significantly lowered.

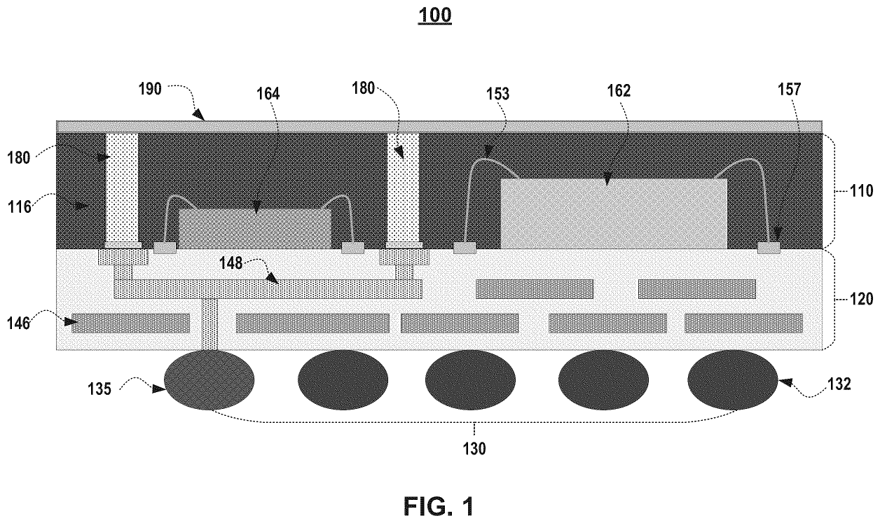

Referring to FIG. 1, a schematic diagram in a perspective side view of an example semiconductor device structure is illustrated, in accordance with some implementations of the present disclosure. As show, the semiconductor device structure can include a chip packaging structure 100 including a substrate 120, a packaging body 110 on a first side of the substrate 120, and a ball grid array (BGA) 130 on a second side of the substrate 120 opposite to the first side. It is noted that, the semiconductor device structure 100 can further include any other suitable components that are not shown in FIG. 1. For example, the semiconductor device can further include a printed circuit board (PCB) on which the chip packaging structure 100 is mounted on via the BGA 130.

The substrate 120 can be any suitable semiconductor substrate having any suitable structure, such as a monocrystalline single-layer substrate, a polycrystalline silicon (polysilicon) single-layer substrate, a polysilicon and metal multi-layer substrate, etc. The substrate 120 can include a signal transmitting wiring structure 146 and a thermal transmitting wiring structure 148 embedded in the substrate. The signal transmitting wiring structure 146 can include any suitable conductive interconnection structures, such as conductive vias and patterned conductive layers, etc., and configured to transmit electric signals. The thermal transmitting wiring structure 148 can include any suitable thermal conductive interconnection structures, such as thermal conductive channels, and configured to transmit heat. The signal transmitting wiring structure 146 and the thermal transmitting wiring structure 148 can be isolated from each other.

In some implementations, the signal transmitting wiring structure 146 can include any suitable conductive materials, such as copper (Cu), nickel (Ni), gold (Au), silver (Ag), platinum (Pt), cobalt (Co), titanium (Ti), chrome (Cr), zirconium (Zr), molybdenum (Mo), ruthenium (Ru), hafnium (Hf), tungsten (W), rhenium (Re), graphite, carbon black, combinations thereof, and/or other materials known to those skilled in the art. The thermal transmitting wiring structure 148 can comprise any suitable thermal conductive materials, such as Ag, Cu, aluminum (Al), aluminum nitride, silicon carbide, W, graphite, zinc (Zn), combinations thereof, and/or other materials known to those skilled in the art. In some implementations, a ratio between a first wiring width of the thermal transmitting wiring structure 148 and a second wiring width of the signal transmitting wiring structure 146 can be in a range between about 1.5 to about 2.

The packaging body 110 can include first die/die stack 162 and second die/die stack 164 that are attached to a first side of the substrate 120 by an adhesive film (not shown). In some implementations, the first die/die stack 162 and the second die/die stack 164 can be any suitable semiconductor dies/die stacks including one or more semiconductor chips. The first die/die stack 162 can include low power chips having maximum operation powers lower than a threshold power value. The second die/die stack 164 can include high power chips having maximum operation powers higher than the threshold power value. For example, the second die/die stack 164 comprises at least one of a micro processing chip, a logic control chip, a power management chip, a driver chip, and an analog chip, and the first die/die stack 162 comprises at least one of a memory chip and a sensing chip. In some implementations, the adhesive film can be any suitable die attach film (DAF).

In some implementations, a plurality of bond pads 157 (also being referred as contact pads, redistribution pads, or similar structures as known to those skilled in the art) can be located on the periphery of first die/die stack 162 and second die/die stack 164, and electrically connected to the signal transmitting wiring structure 146. In some implementations, a plurality of signal wires 153 can be electrically connected between the plurality of bond pads 157 and the first die/die stack 162 or the second die/die stack 164. Thus, electric signals can be transmitted from the first die/die stack 162 and the second die/die stack 164 to the signal transmitting wiring structure 146.

The chip packaging structure 100 can further include a mold compound layer 116 on the substrate 120 to fully cover the first die/die stack 162, second die/die stack 164, and the plurality of signal wires 153. In some implementations, the mold compound layer 116 can be a thermally curable epoxy mold compound or a thermally curable epoxy mold resin. For example, the mold compound layer 116 comprises an inorganic filler (for example, silica), an epoxy resin, a curing agent, a flame retardant, a curing promoter, a release agent, and any other suitable components as known to those skilled in the art.

In some implementations, a thermal conductive cover 190 can cover the mold compound layer 116. At least one thermal conductive structure 180 can be arranged to laterally surround the second die/die stack 164 and vertically penetrating through the mold compound layer 116, and in connection between the thermal conductive cover 190 and the thermal transmitting wiring structure 148. In some implementations, a height of the at least one thermal conductive structure 180 can be greater than the heights of the first die/die stack 162 or the second die/die stack 164. The at least one thermal conductive structure 180 can include a plurality of thermal conductive blocks each vertically penetrating through the mold compound layer 116, and comprising a top surface in contact with the thermal conductive cover 190 and a bottom surface in contact with a thermal pad connected with the thermal transmitting wiring structure 148. In some implementations, a material of the thermal conductive cover 190 and/or the at least one thermal conductive structure 180 has a thermal conductive coefficient greater than 1, such as between 1 and 3. In some implementations, the material of the thermal conductive cover 190 and/or the at least one thermal conductive structure 180 is one of a metal, a ceramic material, or a silicon material.

In some implementations, the ball grid array (BGA) 130 can include a plurality of solder balls 132/135 attached on a second side of the substrate 120 opposite to the first side. BGA 130 can include a plurality of signal solder balls 132 in contact with the signal transmitting wiring structure 146, and at least one thermal solder ball 135 in contact with the thermal transmitting wiring structure 148. That is, the signal solder balls 132 are electrically coupled with the first die/die stack 162 and the second die/die stack 164 to provide transmission of electric signals between the first die/die stack 162 and the second die/die stack 164 and the PCB. The thermal solder balls 135 can be coupled with the thermal conductive structure 180 via the thermal transmitting wiring structure 148, and configured for heat dissipating of the second die/die stack 164.

In some implementations, the signal solder balls 132 and the thermal solder balls 135 can comprise same materials, and can be formed in a same process. For example, the signal solder balls 132 and the thermal solder balls 135 can comprise any suitable metal material, such as Aluminum (Al), Antimony (Sb), Arsenic (As), Bismuth (Bi), Cadmium (Cd), Co, Cu, Ni, Au, Ag, Indium (In), Iron (Fe), Lead (Pb), Phosphorus (P), Tin (Sn), Sulfur (S), Zinc (Zn), Germanium (Ge), etc., and any suitable alloy thereof. In some other implementations, the signal solder balls 132 and the thermal solder balls 135 can comprise different materials. For example, the signal solder balls 132 can include a first material with a high electric conductive coefficient, while the thermal solder balls 135 can include a second material with a high thermal conductive coefficient.

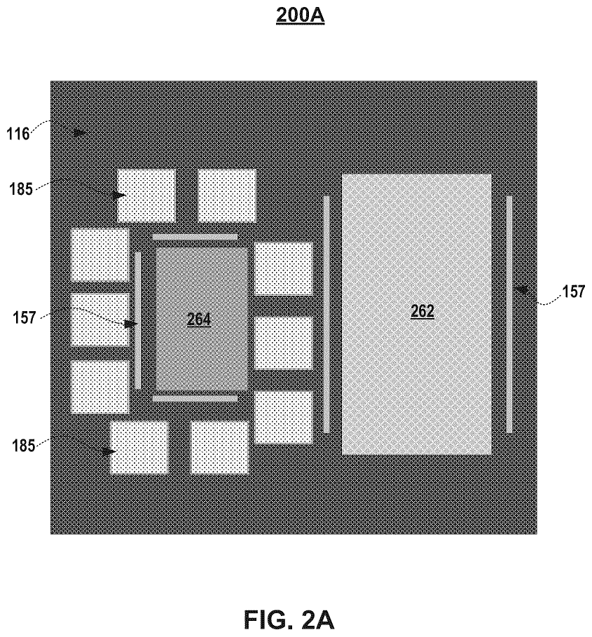

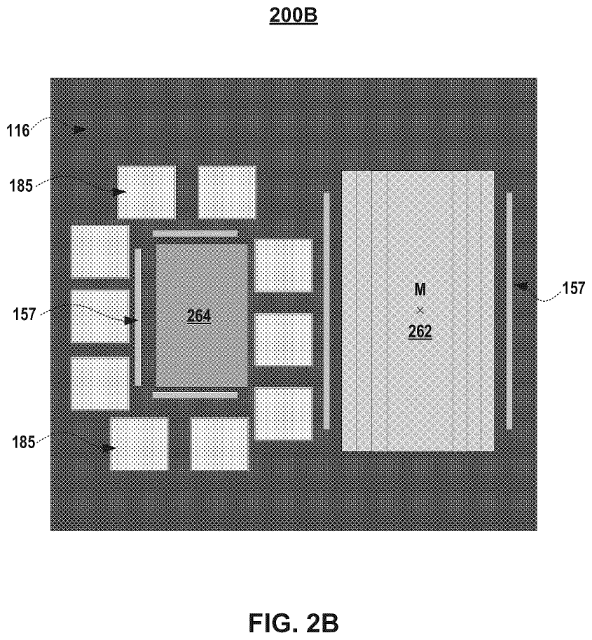

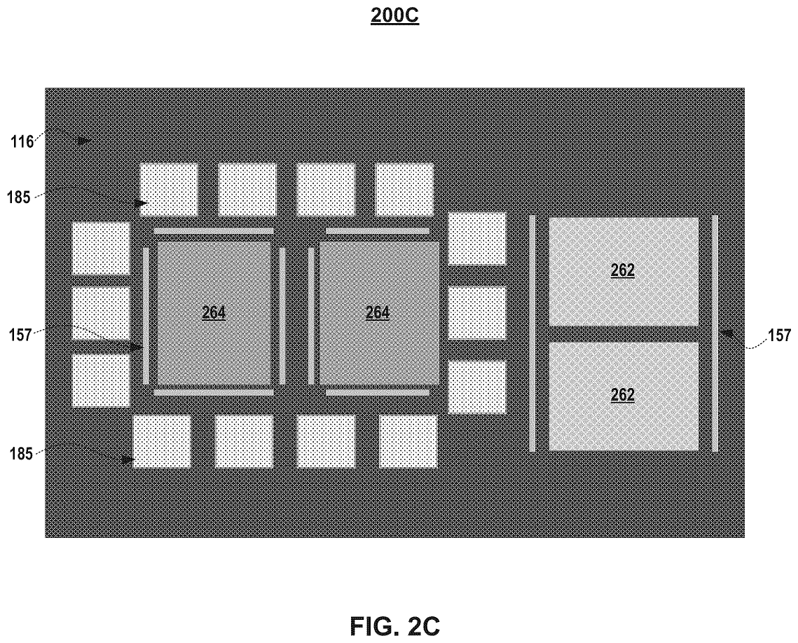

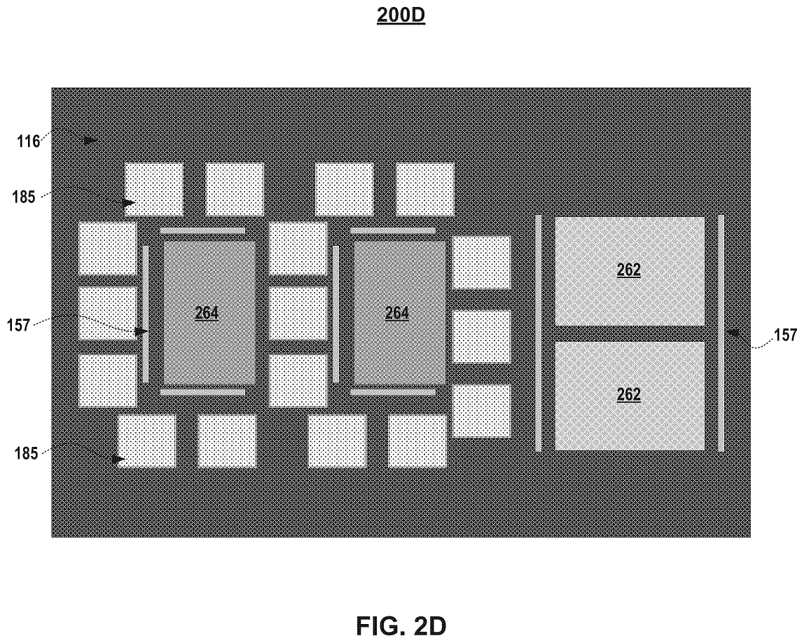

FIGS. 2A-2D illustrate schematic diagrams in a planar view of various designs of exemplary semiconductor structures 200A, 200B, 200C, and 200D respectively, in accordance with various implementations of the present disclosure. It is noted that, the disclosed flexible design can allow different sizes, different shapes, and/or different quantities of thermal conductive structures 180 according to space requirements. In the examples shown in 200A, 200B, 200C, and 200D, the thermal conductive structure 180 can include a plurality of thermal conductive blocks 185 each having an approximate square shape in the planar cross section. In some other implementations not shown, the planar cross section of each thermal conductive structure 180 can have an approximate rectangular shape, an approximate round shape, an approximate oval shape, an approximate trapezoidal shape, etc.

As shown in FIG. 2A, the plurality of thermal conductive blocks 185 can be arranged to laterally surround a first chip 264. The first chip 264 can be a high power chip having a first operating power higher than a threshold power value. A second chip 264 outside the plurality of thermal conductive blocks 185 can be a low power chip having a second operating power higher than a threshold power value. In some implementations, the first chip 264 can be a micro processing chip, a logic control chip, a power management chip, a driver chip, or an analog chip. The second chip 262 can be a memory chip or a sensing chip.

In some other implementations as shown in FIG. 2B, a plurality of second chips 262 (e.g., number M of low power chips) can be stacked in the vertical direction to form a die stack. Due to the thermal management, the first chips 264 are not stacked together to form a die stack. Instead, the first chips 264 can be arranged side by side and be laterally surrounded by the plurality of thermal conductive blocks 185, as shown in FIG. 2C. In some other implementations as shown in FIG. 2D, some of the plurality of thermal conductive blocks 185 can be located between adjacent first chips 264.

In some implementations, a first lateral area of the planar cross section of each thermal conductive block 185 can be around 1 mm. In some implementations, a ratio between the first lateral area of each thermal conductive block 185 and a second lateral area of the first chip 264 can be in a range between about 1/20 and about 1/10. It is noted that, although the plurality of thermal conductive blocks 185 surround the first chip 264 for one circle as shown in FIGS. 2A-2D, in some other implementations not shown, the plurality of thermal conductive blocks 185 can surround the first chip 264 for more than one circle.

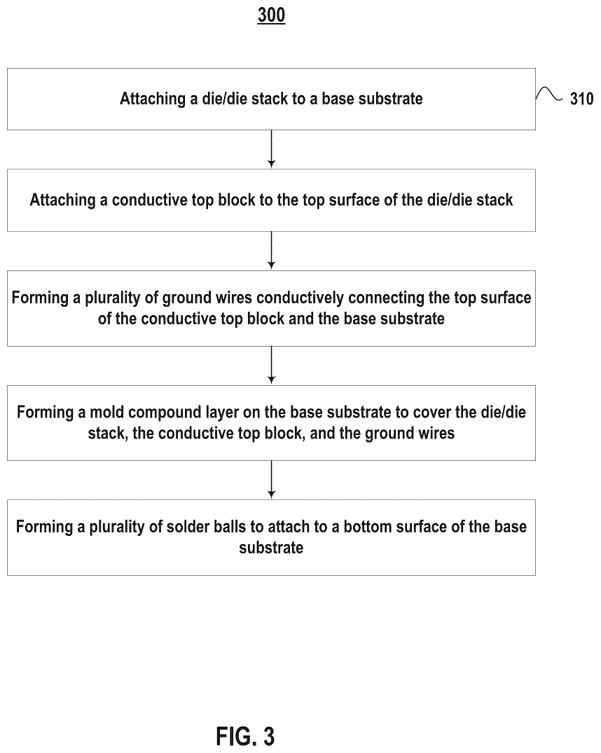

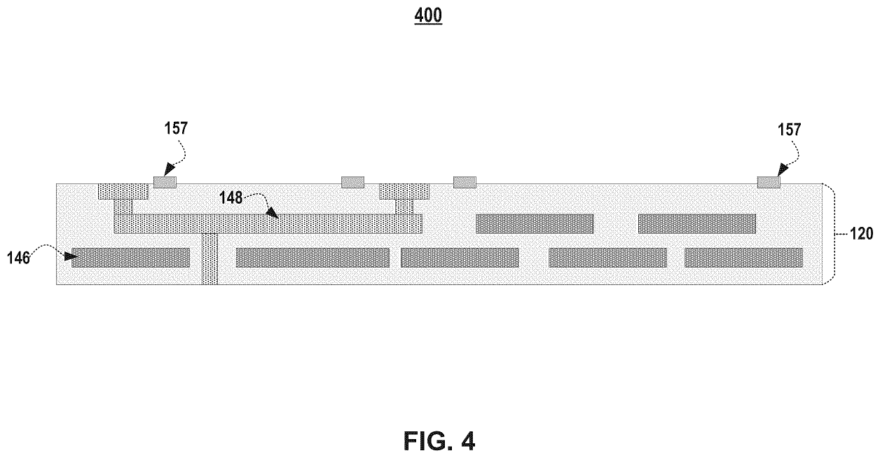

Referring to FIG. 3, a flow diagram of an exemplary method for forming a semiconductor structure is illustrated in accordance with some implementations of the present disclosure. It should be understood that the operations and/or steps shown in FIG. 3 are not exhaustive and that other operations can be performed as well before, after, or between any of the illustrated operations. FIGS. 4-9 illustrate schematic diagrams in a perspective side view of an exemplary semiconductor structure at certain fabricating steps of the method shown in FIG. 3, in accordance with some implementations of the present disclosure.

As shown in FIG. 3, the method 300 starts at operation 310, in which a substrate including a signal transmitting wiring structure and a thermal transmitting wiring structure can be provided. FIG. 4 illustrates a schematic diagram in a perspective side view of an exemplary semiconductor structure after operation 310 of the method 300 shown in FIG. 3, in accordance with some implementations of the present disclosure.

As shown in FIG. 4, in some implementations, the substrate 120 can include the signal transmitting wiring structure 146 and the thermal transmitting wiring structure 148 embedded therein. The substrate 120 can be any suitable semiconductor substrate having any suitable structure, such as a monocrystalline single-layer substrate, a polycrystalline silicon (polysilicon) single-layer substrate, a polysilicon and metal multi-layer substrate, etc.

The signal transmitting wiring structure 146 can include any suitable conductive interconnection structures, such as conductive vias and patterned conductive layers, etc., and configured to transmit electric signals. The thermal transmitting wiring structure 148 can include any suitable thermal conductive interconnection structures, such as thermal conductive channels, and configured to transmit heat. The signal transmitting wiring structure 146 and the thermal transmitting wiring structure 148 can be isolated from each other.

In some implementations, the signal transmitting wiring structure 146 can include any suitable conductive materials, such as copper (Cu), nickel (Ni), gold (Au), silver (Ag), platinum (Pt), cobalt (Co), titanium (Ti), chrome (Cr), zirconium (Zr), molybdenum (Mo), ruthenium (Ru), hafnium (Hf), tungsten (W), rhenium (Re), graphite, carbon black, combinations thereof, and/or other materials known to those skilled in the art. The thermal transmitting wiring structure 148 can comprise any suitable thermal conductive materials, such as Ag, Cu, aluminum (Al), aluminum nitride, silicon carbide, W, graphite, zinc (Zn), combinations thereof, and/or other materials known to those skilled in the art. In some implementations, a ratio between a first wiring width of the thermal transmitting wiring structure 148 and a second wiring width of the signal transmitting wiring structure 146 can be in a range between about 1.5 to about 2.

In some implementations, a plurality of bond pads 157 (also being referred as contact pads, redistribution pads, or similar structures as known to those skilled in the art) can be formed on a first surface of the substrate 120, and can be electrically connected to the signal transmitting wiring structure 146. In some implementations, an array of ball pads (not showing) can be formed on a second surface the substrate 120 opposite to the first surface. The array of ball pads can be used to form an array of BGA in subsequent processes.

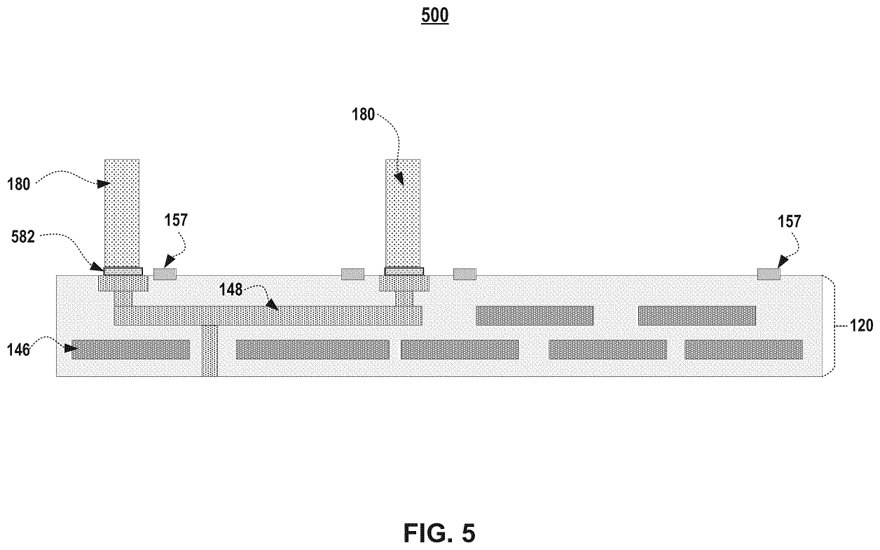

Referring back to FIG. 3, the method 300 can proceed to operation 320, in which at least one thermal conductive structure can be formed on a first side the substrate. FIG. 5 illustrates a schematic diagram in a perspective side view of an exemplary semiconductor structure 500 after operation 320 of the method 300 shown in FIG. 3, in accordance with some implementations of the present disclosure.

In some implementations, the at least one thermal conductive structure 180 can be formed on the first surface of the substrate 120, and in thermal contact with the thermal transmitting wiring structure 148. In some implementations, the at least one thermal conductive structure 180 can laterally surround at least one region for attaching at least one first chip having a first operating power higher than a threshold power value in subsequent processes. In some implementations, forming the at least one thermal conductive structure 180 can include forming a plurality of thermal conductive blocks (e.g., thermal conductive blocks shown in FIGS. 2A-2D) each on a thermal pad 582 on the first side of the substrate 120 and connected with the thermal transmitting wiring structure 148.

In some implementations, a material of the at least one thermal conductive structure 180 has a thermal conductive coefficient greater than 1, such as between 1 and 3. In some implementations, the material of the at least one thermal conductive structure 180 is one of a metal, a ceramic material, or a silicon material. In some implementations, a first lateral area of the planar cross section of each thermal conductive block can be around 1 mm.

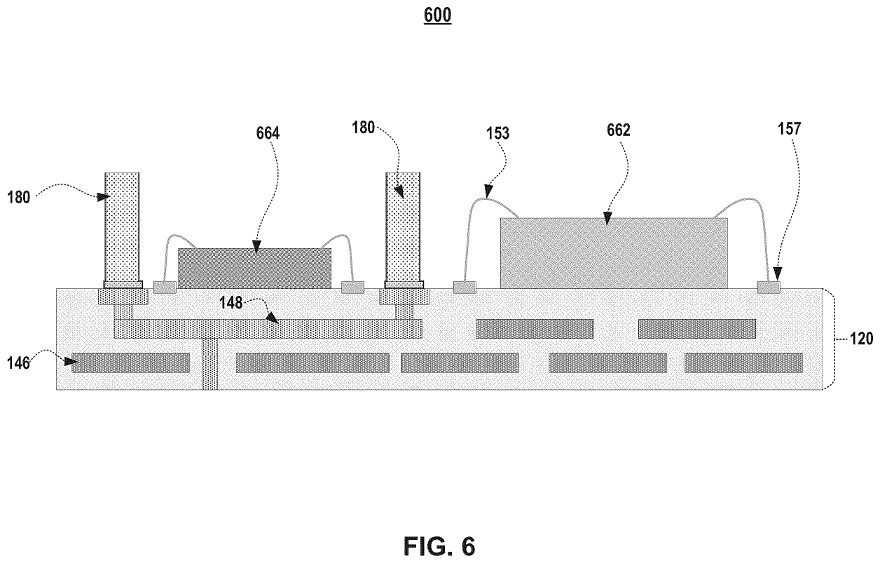

Referring back to FIG. 3, the method 300 can proceed to operation 330, in which a first chip can be formed on the first side of the substrate and laterally surrounded by the at least one thermal conductive structure. In some implementations, operation 330 further comprises forming a second chip on the first side of the substrate and outside of the at least one thermal conductive structure. FIG. 6 illustrates a schematic diagram in a perspective side view of an exemplary semiconductor structure 600 after operation 330 of the method 300 shown in FIG. 3, in accordance with some implementations of the present disclosure.

In some implementations, the first chip 664 and/or the second chip 662 can be attached on the first surface of the substrate 120 by using any suitable adhering or fastening means known in the art. In some implementations, an adhesive film (not shown), such as a die attach film (DAF), can be attached to a bottom surface of the first chip 664 and/or the second chip 662. And then the first chip 664 and/or the second chip 662 can be permanently attached or secured to the first surface of the substrate 120.

In some implementations, the first chip 664 can be a high power chip having a first operating power higher than a threshold power value, and can be attached in a region surrounded by the at least one thermal conductive structure 180. The second chip 664 can be a low power chip having a second operating power higher than a threshold power value, and can be attached in a region outside the at least one thermal conductive structure 180. In some implementations, the first chip 664 can be a micro processing chip, a logic control chip, a power management chip, a driver chip, or an analog chip. The second chip 662 can be a memory chip or a sensing chip.

In some implementations, a plurality of second chips 662 can be stacked in the vertical direction to form a die stack. Due to the thermal management, the first chips 264 are not stacked together to form a die stack. Instead, the first chips 664 can be arranged side by side and be laterally surrounded by the at least one thermal conductive structure 180. In some implementations, a ratio between the first lateral area of each thermal conductive block and a second lateral area of the first chip 664 can be in a range between about 1/20 and about 1/10.

In some implementations, operation 330 further comprises wiring the first chip 664 and/or the second chip 662 to the plurality of bond pads 157. For example, a plurality of signal wires 153 can be formed to electrically connect the plurality of bond pads 157 to the first chip 664 and/or the second chip 662, such that the first chip 664 and/or the second chip 662 is electrically coupled with the signal transmitting wiring structure 146.

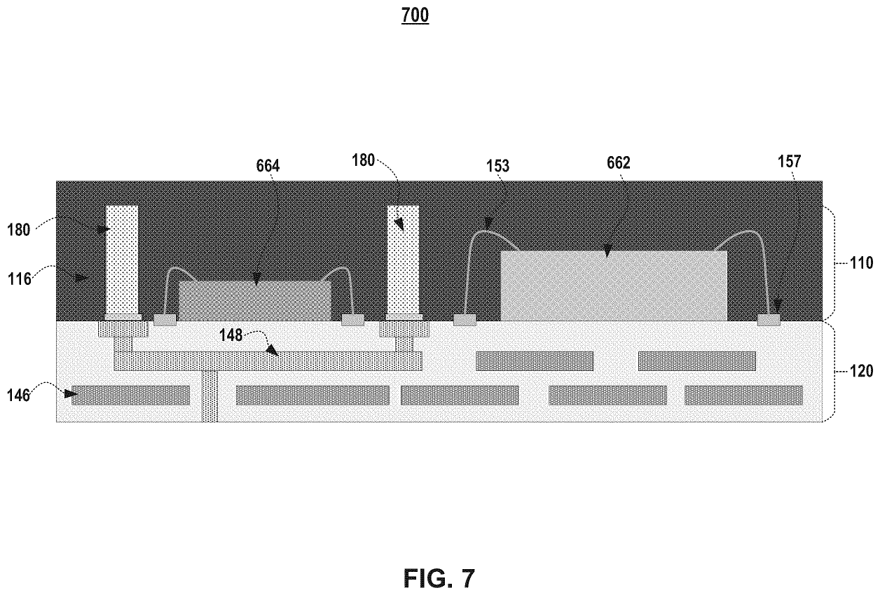

Referring back to FIG. 3, the method 300 can proceed to operation 340, in which a mold compound layer can be formed on the first side of the substrate to cover the chips and the at least one thermal conductive structure. FIG. 7 illustrates a schematic diagram in a perspective side view of an exemplary semiconductor structure 700 after operation 340 of the method 300 shown in FIG. 3, in accordance with some implementations of the present disclosure.

In some implementations, a mold compound layer 116 can be formed on the first side of the substrate 120 to cover the first chip 664 and/or the second chip 662, the at least one thermal conductive structure 180, and the plurality of signal wires 153. In some implementations, the mold compound layer 116 can be formed by any suitable materials, such as a thermally curable epoxy mold compound material or a thermally curable epoxy mold resin. For example, the mold compound layer 116 can be formed by using an inorganic filler (e.g., silica), an epoxy resin, a curing agent, a flame retardant, a curing promoter, a release agent, and any other suitable components as known to those skilled in the art.

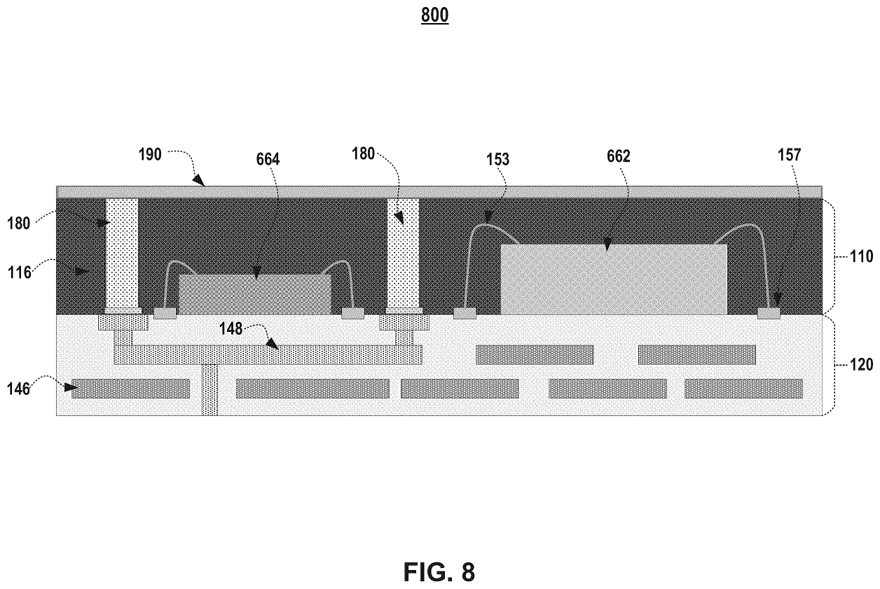

Referring back to FIG. 3, the method 300 can proceed to operation 350, in which a thermal conductive cover can be formed on mold compound layer and in contact with the at least one thermal conductive structure. FIG. 8 illustrates a schematic diagram in a perspective side view of an exemplary semiconductor structure 800 after operation 350 of the method 300 shown in FIG. 3, in accordance with some implementations of the present disclosure.

In some implementations, an upper portion of the mold compound layer 116 can be removed by any suitable process, such as chemical mechanical polishing (CMP) or griding, such that the at least one thermal conductive structure 180 can be exposed. A thermal conductive cover 190 can then be formed on the remaining portion of the mold compound layer 116, and in directed contact with the at least one thermal conductive structure 180. As such, the heat produced by the first chip 664 can be dispersed by the at least one thermal conductive structure 180 to both surface of the formed semiconductor, i.e., the thermal conductive cover 190 and the thermal transmitting wiring structure 148. In some implementations, the thermal conductive cover 190 can be formed by a thermal conductive having a thermal conductive coefficient greater than 1, such as between 1 and 3. In some implementations, the material of the thermal conductive cover 190 is one of a metal, a ceramic material, or a silicon material.

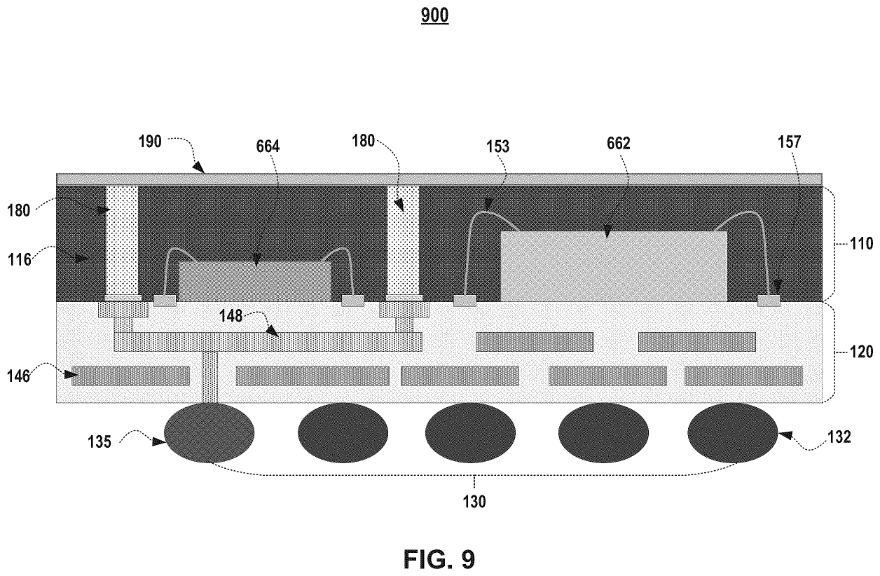

Referring back to FIG. 3, the method 300 can proceed to operation 360, in which a ball grid array (BGA) can be formed on a second side of the semiconductor structure. FIG. 9 illustrates a schematic diagram in a perspective side view of an exemplary semiconductor structure 900 after operation 360 of the method 300 shown in FIG. 3, in accordance with some implementations of the present disclosure.

As shown in FIG. 9, a ball grid array (BAG) 130 can be formed on a second surface of the base substrate 120 opposite to the packaging body 110. The BAG 130 can comprise a plurality of solder balls 132/135 attached on the array of ball pads (not shown) on the second surface of the base substrate 120. The plurality of signal solder balls 132 can be formed in contact with the signal transmitting wiring structure 146, and at least one thermal solder ball 135 can be formed in contact with the thermal transmitting wiring structure 148. As such, the thermal solder balls 135 can be coupled with the thermal conductive structure 180 via the thermal transmitting wiring structure 148, and configured for dissipating the operation heat generated by the first chip 664. The signal solder balls 132 can be electrically coupled with the first chip 664 and the second chip 662 to provide signal transmission.

In some implementations, the signal solder balls 132 and the thermal solder balls 135 can be formed simultaneously in a same process by using a same materials. For example, the signal solder balls 132 and the thermal solder balls 135 can be formed by using any suitable metal material, such as Aluminum (Al), Antimony (Sb), Arsenic (As), Bismuth (Bi), Cadmium (Cd), Co, Cu, Ni, Au, Ag, Indium (In), Iron (Fe), Lead (Pb), Phosphorus (P), Tin (Sn), Sulfur (S), Zinc (Zn), Germanium (Ge), etc., and any suitable alloy thereof. In some other implementations, the signal solder balls 132 and the thermal solder balls 135 can be formed by different processes and using different materials. For example, the signal solder balls 132 can be formed by using a first material with a high electric conductive coefficient, while the thermal solder balls 135 can be formed by using a second material with a high thermal conductive coefficient.

It is noted that, although not shown, the method 300 can further comprise any other suitable operations to further form the semiconductor structure. For example, the formed chip packaging structure 900 can be attached to a printed circuit board (PCB). And the plurality of signal solder balls 132 and the thermal solder balls 135 can be used to provide mechanical connection between the chip packaging structure 900 and the PCB.

Accordingly, the present disclosure provides chip packaging structures with a high thermal conductivity. The fabricating process can be modularized. In a disclosed chip packaging space, a certain number of thermal conductive structures of same or different sizes can be packaged around the chip stack and connected between a metal layer on the front of the package and the solder balls on the back to realize a strong heat dissipation effect. Through the surface mount technology (SMT) packaging process, the connection between the high thermal conductivity material and the copper layer of the substrate and the connection of the surface metal coating can be realized. As such, high thermal conductivity within the packaging structure can be obtained, thereby significantly improving the product heat dissipation and improving the product performance.

The disclosed fabricating process for forming the disclosed chip packaging structures can be modularized, thus it is simple. Conventional equipment can be used for the disclosed fabricating process without much cost investment. The modular packaging solution can be adopted to reduce the difficulty of packaging and processing, which is conducive to mass production. The disclosed design can achieve better internal heat conduction effect of the chip packaging structure without changing the external dimensions of the existing package and the existing packaging materials. The thermal conductive structures can select a material with a high thermal conductivity and a high mechanical strength, so that the whole chip packaging structure can have a better heat dissipation effect and a better mechanical property. Further, the disclosed fabricating process can allow flexible design of different sizes and/or different quantities of thermal conductive structures according to space requirements. Therefore, the heat dissipation conditions of high-power chips within the disclosed chip packaging structures can be significantly improved, and the operating temperatures of the disclosed chip packaging structures significantly lowered.

The foregoing description of the specific implementations will so fully reveal the general nature of the present disclosure that others can, by applying knowledge within the skill of the art, readily modify and/or adapt, for various applications, such specific implementations, without undue experimentation, and without departing from the general concept of the present disclosure. Therefore, such adaptations and modifications are intended to be within the meaning and range of equivalents of the disclosed implementations, based on the disclosure and guidance presented herein. It is to be understood that the phraseology or terminology herein is for the purpose of description and not of limitation, such that the terminology or phraseology of the present specification is to be interpreted by the skilled artisan in light of the disclosure and guidance.

Implementations of the present disclosure have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The Summary and Abstract sections can set forth one or more but not all exemplary implementations of the present disclosure as contemplated by the inventor(s), and thus, are not intended to limit the present disclosure and the appended claims in any way.

The breadth and scope of the present disclosure should not be limited by any of the above-described exemplary implementations, but should be defined only in accordance with the following claims and their equivalents.

What is claimed is:

1. A chip packaging structure, comprising:
a substrate, comprising:
a signal transmitting wiring structure embedded in the substrate, and
a thermal transmitting wiring structure embedded in the substrate;
a first chip on the substrate and electrically connected with the signal transmitting wiring structure; and
at least one thermal conductive structure on the substrate, in thermal contact with the thermal transmitting wiring structure, and laterally surrounding the first chip.

2. The chip packaging structure of claim 1, further comprising:
a mold compound layer on the substrate and covering the first chip, wherein the at least one thermal conductive structure is embedded in the mold compound layer; and
a thermal conductive cover on the mold compound layer and in thermal contact with the at least one thermal conductive structure.

3. The chip packaging structure of claim 1, further comprising:
a ball grid array on a side of substrate opposite to the first chip and the at least one thermal conductive structure, the ball grid array comprising:
a plurality of signal solder balls in contact with the signal transmitting wiring structure, and
at least one thermal solder ball in contact with the thermal transmitting wiring structure.

4. The chip packaging structure of claim 2, wherein the at least one thermal conductive structure comprises:
a plurality of thermal conductive blocks each vertically penetrating through the mold compound layer and comprising a top surface in contact with the thermal conductive cover and a bottom surface in contact with a thermal pad connected with the thermal transmitting wiring structure.

5. The chip packaging structure of claim 4, wherein:
a ratio between a first lateral area of each thermal conductive block and a second lateral area of the first chip is in a range between about 1/20 and about 1/10.

6. The chip packaging structure of claim 1, further comprising:
a second chip on the substrate and outside the at least one thermal conductive structure.

7. The chip packaging structure of claim 6, wherein:
a first operating power of the first chip is greater than a second operating power of the second chip.

8. The chip packaging structure of claim 6, wherein:
the first chip comprises at least one of a micro processing chip, a logic control chip, a power management chip, a driver chip, and an analog chip; and
the second chip comprises at least one of a memory chip and a sensing chip.

9. The chip packaging structure of claim 1, further comprising:
a third chip on the substrate and beside the first chip, and being laterally surrounded by the at least one thermal conductive structure.

10. The chip packaging structure of claim 9, wherein:
a portion of the at least one thermal conductive structure is located between the third chip and the first chip.

11. The chip packaging structure of claim 1, wherein:
a material of the at least one thermal conductive structure has a thermal conductive coefficient greater than 1.

12. The chip packaging structure of claim 11, wherein:
the material is one of a metal, a ceramic material, or a silicon material.

13. The chip packaging structure of claim 1, wherein:
a ratio between a first wiring width of the thermal transmitting wiring structure and a second wiring width of the signal transmitting wiring structure is in a range between about 1.5 to about 2.

14. A method of forming a chip packaging structure, comprising:
providing a substrate, comprising:
a signal transmitting wiring structure embedded in the substrate, and
a thermal transmitting wiring structure embedded in the substrate;
forming at least one thermal conductive structure on a first side of the substrate and in thermal contact with the thermal transmitting wiring structure;
forming a first chip on the first side of the substrate and laterally surrounded by the first chip; and
electrically connecting the first chip with the signal transmitting wiring structure.

15. The method of claim 14, further comprising:
forming a mold compound layer on the first side of the substrate to cover the first chip and the at least one thermal conductive structure; and
forming a thermal conductive cover on the mold compound layer on the mold compound layer and in thermal contact with the at least one thermal conductive structure.

16. The method of claim 15, further comprising:
forming a ball grid array on a second side of substrate opposite to the first side, comprising:
forming a plurality of signal solder balls in contact with the signal transmitting wiring structure, and
forming at least one thermal solder ball in contact with the thermal transmitting wiring structure.

17. The method of claim 14, wherein forming the at least one thermal conductive structure comprises:
forming a plurality of thermal conductive blocks each on a thermal pad on the first side of the substrate and connected with the thermal transmitting wiring structure.

18. The method of claim 14, wherein the at least one thermal conductive structure and the first chip are formed on the substrate by using a surface mount technology (SMT) process.

19. The method of claim 15, further comprising:
forming a second chip on the first side of the substrate and outside the at least one thermal conductive structure,
wherein a first operating power of the first chip is greater than a second operating power of the second chip.

20. A semiconductor structure, comprising:
a printed circuit board;
a chip packaging structure, comprising:
a substrate, comprising:
a signal transmitting wiring structure embedded in the substrate, and
a thermal transmitting wiring structure embedded in the substrate;
a first chip on the substrate and electrically connected with the signal transmitting wiring structure; and
at least one thermal conductive structure on the substrate, in thermal contact with the thermal transmitting wiring structure, and laterally surrounding the first chip; and
a ball grid array connected between the printed circuit board and the chip packaging structure, comprising:
a plurality of signal solder balls in contact with the signal transmitting wiring structure, and
at least one thermal solder ball in contact with the thermal transmitting wiring structure.
